(19) United States
(12) Patent Application Publication
(10) Pub. No.: US 2013/0089679 A1
(43) Pub. Date: Apr. 11, 2013

(54) PLASMA-ENHANCED DEPOSITION OF MANGANESE-CONTAINING FILMS FOR VARIOUS APPLICATIONS USING AMIDINATE MANGANESE PRECURSORS

(71) Applicants: Christian Dussarrat, Wilmington, DE (US); Vincent M. Omarjee, Grenoble (FR); Clement Lansalot-Matras, Tsukuba (JP)

(72) Inventors: Christian Dussarrat, Wilmington, DE (US); Vincent M. Omarjee, Grenoble (FR); Clement Lansalot-Matras, Tsukuba (JP)

(73) Assignees: L'Air Liquide Societe Anonyme pour l'Etude et l'Exploitation des Procedes Georges Claude, Paris (FR); American Air Liquide, Inc., Fremont, CA (US)

(21) Appl. No.: 13/269,140

(22) Filed: Oct. 7, 2011

(51) Int. Cl. C23C 16/06

(52) U.S. Cl. 427/576

(57) ABSTRACT

The disclosure relates to a process for depositing a Manganese-containing film comprising the step of providing a metal guanidinate and/or metal amidinate precursor, suitable for plasma deposition at temperature equal or lower than 500 degrees C., to a plasma deposition process comprising a deposition temperature equal or lower than 500 degrees C.

### TECHNICAL FIELD

The present invention relates to a process for the use of metal amidinate metal precursors for the deposition of metal containing film via Plasma Enhanced Atomic Layer Deposition (PEALD) or Plasma Enhanced Chemical Vapor Deposition (PECVD).

### BACKGROUND ART

Advancement of semiconductor devices requires the realization of ultrathin diffusion barrier layer between Cu interconnect and insulating layers (low-k). Typically, TaN/Ta are used as barrier. In recent studies, it was found that Mn containing barrier can have significant advantage reducing electromigration issues and can have enhanced barrier properties. Upon annealing, the Mn deposited in a Mn-containing film (such as Cu—Mn) typically diffuses and form what is called a “self-forming barrier”.

Haneda et al. (APPLIED PHYSICS LETTERS 90, 2521072, 2007) used Cu—Mn co-sputtered to deposit a Mn-containing barrier. Good barrier properties were confirmed. However, the use of sputtering techniques is not expected to be feasible for future transistor dimensions.

Gordon et al. (AMC 2008) used bis(diisopropylpentylamidinato) manganese in CVD. It is a solid with a melting point of ˜60 degrees C. However, it is not clear if manganese or its oxide is deposited using the technique. However, the method yielded the formation of a MnSiOx layer that was an effective barrier to diffusion of Cu, O2 or H2O into the underlaying layers.

Among the standard Mn precursors, Manganese cyclopentadienyls (possibly substituted) are also used for Mn-containing film deposition.

Metal bis amidinate precursors can be prepared in general from the reaction of the corresponding metal bis chloride with two equivalents of lithium amidinate as described in Inorg. Chem. 2003, 42, 7951-7958.

### DISCLOSURE OF INVENTION

The invention may be defined in part by reference to the following paragraphs [0008]-[00020]:

A process for depositing a Manganese-containing film comprising the step of providing a metal guanidinate and/or metal amidinate precursor, suitable for plasma deposition at temperature equal or lower than 500 degrees C., to a plasma deposition process comprising a deposition temperature equal or lower than 500 degrees C.

The method of paragraph [0008], wherein the deposition temperature is at a temperature of 20-500 degrees C.

The method of paragraph [0008], wherein the deposition temperature is at a temperature of 50-300 degrees C.

The method of paragraph [0008], wherein the deposition temperature is at a temperature of 100-300 degrees C.

The method of paragraph [0008], wherein the deposition temperature is at a temperature of 200-300 degrees C.

The method of any one of paragraphs [0008]-[00012], wherein the metal containing film is deposited on a substrate coated with one or more of Ru, Ta, TaN, SiO₂.

The method of any one of paragraphs [0008]-[00012] or the combination of any one of paragraphs [0008]-[00012] with paragraph [00013], further comprising a step of providing at least one co-reactant amine or reducing agent to the plasma deposition process.

The method of any one of paragraphs [0008]-[00012] or the combination of any one of paragraphs [0008]-[00012] with one or both of paragraphs [00013] and [00014], further comprising a step of providing to the plasma deposition process at least one co-reactant oxygen source selected from O₂, O₃, H₂O, H₂O₂, NO, NO₂, or a carboxylic acid.

The method of any one of paragraphs [0008]-[00012] or the combination of any one of paragraphs [0008]-[00012] with any one of or any combination of paragraphs [00013]-[00015], wherein the plasma deposition process is a PECVD process.

The method of paragraph [00014] wherein the plasma deposition process is a PEALD process comprising a plurality of cycle.

The method of any one of paragraphs [0008]-[00012] or the combination of any one of paragraphs [0008]-[00012] with any one of or any combination of paragraphs [00013]-[00017], wherein the metal film is substantially pure metal.

The method of any one of paragraphs [0008]-[00012] or the combination of any one of paragraphs [0008]-[00012] with any one of or any combination of paragraphs [00013]-[00018], wherein the film is a Manganese-containing film and the suitable metal precursor has the structure of compound (II) wherein M is Manganese; and R₁ and R₃ are independently selected from H, a C1-C5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups.

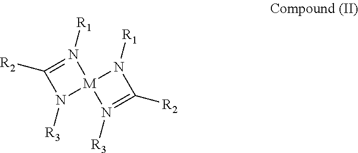

The method of any one of paragraphs [0008]-[00012] or the combination of any one of paragraphs [0008]-[00012] with any one of or any combination of paragraphs [00013]-[00018], where the preferred metal precursor is bis(N,N′-diisopropylpentylamidinato) Manganese (II).

The present invention relates to a process for the use of Cobalt and Nickel metal amidinate precursors for the deposition of metal containing films via Plasma Enhanced Atomic Layer Deposition (PEALD) or Plasma Enhanced Chemical Vapor Deposition (PECVD). Plasma improves deposition rates and/or film properties, especially at low deposition temperatures. The preferred metal of the invention is Nickel.

In some embodiments, the present invention provides methods of depositing pure metal Manganese film by plasma enhanced atomic layer deposition (PEALD) and plasma enhanced chemical vapor deposition (PECVD). “Pure metal” is defined as at least 90% metal such as 95% or more metal, 99% or more metal or 99.9% or more metal.

In some embodiments of the invention, Manganese amidinate or Manganese guanidinate is used at low deposition temperatures.

In some embodiments, the metal deposition method includes the steps of providing a substrate; providing a vapor of a Manganese guanidinate or a Manganese amidinate precursor; and contacting the vapor including the at least one Copper precursor with the substrate (and typically directing the vapor to the substrate) to form a Manganese-containing layer on at least one surface of the substrate at temperature of 400 degrees C. or lower, preferably between 50 and 300 degrees C.

In one embodiment of the invention, the Manganese precursor is represented by compound (II)

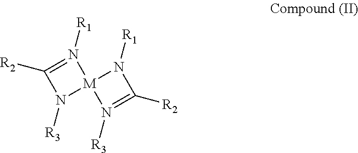

wherein:

M is Manganese; and

R₁ and R₃ are independently selected from H, a C1-C5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups. An exemplary species of the metal precursor is bis(N,N′-diisopropylpentylamidinato) manganese (II).

Deposition conditions for the invention include temperatures in the range of 20-500 degrees C., preferably below 300 degrees C. such as 50-300 degrees C., 100-250 degrees C., or 200-250 degrees C. Deposition conditions for the invention may also include pressures ranging from 0.5 mTorr to 20 Torr to deposit films having the general formula M, MₖSiₗ, MₙOₘ or MₓN_{y}O_{z}. Film composition will be dependent on the application. Where k, l, m, n, x, y range from 1 to 6, inclusive. The deposition may include one or more co-reactants such as an amine containing reactant or a reducing agent. Exemplary co-reactants are H₂, NH₃, diethylsilane, BuNH₂, B₂H₆, GeH₄, SnH₄, AlH₃, or an alkyl silane containing a Si—H bond. The deposition may include one or more co-reactant oxygen sources preferably O₂, O₃, H₂O, H₂O₂, NO, NO₂, a carboxylic acid, dimethylsilane. The metal precursor may be delivered in neat form or in a blend with a suitable solvent, preferably Ethyl benzene, Xylenes, Mesitylene, Decane, or Dodecane in suitable concentrations.

In some but non-limiting embodiments, preferred applications could be Manganese deposition on silicon, metal deposition on Ta, TaN or WN to ultimately form a metal layer, and metal oxide deposition for ReRAM applications

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

What is claimed is:

1. A process for depositing a Manganese-containing film comprising the step of providing a Manganese guanidinate and/or Manganese amidinate precursor, suitable for plasma deposition at temperature equal or lower than 500 degrees C., to a plasma deposition process comprising a deposition temperature equal or lower than 500 degrees C.

2. The method of claim 1, wherein the deposition temperature is at a temperature of 20-500 degrees C.

3. The method of claim 1, wherein the deposition temperature is at a temperature of 50-300 degrees C.

4. The method of claim 1, wherein the deposition temperature is at a temperature of 100-300 degrees C.

5. The method of claim 1, wherein the deposition temperature is at a temperature of 200-300 degrees C.

6. The method of claim 1, wherein the metal containing film is deposited on a substrate coated with one or more of Ru, Ta, TaN, SiO₂.

7. The method of claim 1, further comprising a step of providing at least one co-reactant amine or reducing agent to the plasma deposition process.

8. The method of claim 1, further comprising a step of providing to the plasma deposition process at least one co-reactant oxygen source selected from O₂, O₃, H₂O, H₂O₂, NO, NO₂, or a carboxylic acid.

9. The method of claim 1, wherein the plasma deposition process is a PECVD process.

10. The method of claim 7, wherein the plasma deposition process is a PEALD process comprising a plurality of cycle.

11. The method of claim 1, wherein the metal film is substantially pure metal.

12. The method of claim 1, wherein the film is a Nickel containing film and the suitable metal precursor has the structure of compound (II) 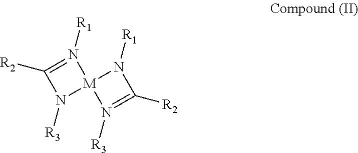
wherein M is Manganese; and R₁ and R₃ are independently selected from H, a C1-C5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups.

13. The method of claim 12, where the preferred metal precursor is bis(N,N′-diisopropylpentylamidinato) manganese (II).
